(19) United States
(12) Patent Application Publication
(10) Pub. No.: US 2009/0190298 A1
(43) Pub. Date: Jul. 30, 2009

(54) FUNCTIONAL AND ORNAMENTAL COVER FOR FLASH MEMORY STICK DEVICE

(76) Inventor: Dean PANAS, New Berlin, WI (US)

Correspondence Address: JOSEPH S. HEINO, ESQ.;DAVIS & KUELTHAU, S.C., 111 E. KILBOURN, SUITE 1400, MILWAUKEE, WI, 53202-6613, US

(21) Appl. No.: 12/356,189

(22) Filed: Jan. 20, 2009

Related U.S. Application Data
(60) Provisional application No. 61/023,160, filed on Jan. 24, 2008.

(51) Int. Cl. H05K 5/00

(52) U.S. Cl. 361/679.32

(57) ABSTRACT

A memory stick cover is configured to be used by a consumer for receiving and protecting the connector of a memory stick when the memory stick is being transported and otherwise not in use. The memory stick cover is removable from the connector end and placed over the opposite end of the memory stick when the memory stick is connected to a computer. The memory stick cover of the present invention is somewhat of a novelty item as it may be configured of a moldable material such as rubber. Alternatively, it may consist of a hard-covered material with a rubber or other pliable material insert, the insert being configured to receive and protect the male connector of the memory stick.

This application claims the benefit and priority of U.S. Provisional Patent Application No. 61/023,160 filed Jan. 24, 2008.

### FIELD OF THE INVENTION

The present invention relates generally to the field of computers and peripheral devices used with computers. More specifically, the present invention relates to a cover for a flash memory stick device that is both functional for protecting the device during non-use as well as ornamental whether the device is being used or not. It also relates to such a cover that can be alternatively configured to serve as an item to fulfill the ornamental and decorative interests of users of the cover.

### BACKGROUND OF THE INVENTION

The current demand for computers and for peripheral computer devices has exploded as manufacturers of computers and peripheral computer devices attempt to keep up with consumer expectations. Although computers are viewed as a “tool” by most consumers, the same consumers also want to experience some level of “fun” in using their computers.

One such peripheral computer device is the “flash memory stick device,” also known as a “flash stick,” “flash memory stick,” “memory stick,” “jump drive” or “universal serial bus (USB) flash drive.” It is to be understood that the term “memory stick” as used in this application incorporates all of these terms and any others that may be used to describe the same device, including like devices not yet fully configured and names not yet given to such devices. The memory stick device uses a non-volatile computer memory that does not require an independent power supply to maintain the information stored on a solid state computer chip housed within the memory stick. Flash memory can be electrically erased and reprogrammed. Generally speaking, such memory sticks are typically small, lightweight and highly portable, the memory stick being easily insertable to, and removable from, the computing device that it is used with. However, as compared to conventional floppy disks, for example, memory sticks are faster, hold more data and are generally more reliable and durable. Hence, their popularity and the great likelihood that such devices will be used for many years to come.

As alluded to above, memory sticks consist generally of a small printed circuit board that is housed in a plastic or metal casing, such casing being sturdy enough to be carried in a consumer's pocket or even on his or her keychain. Only the male connector of the memory stick, which is insertable into a like-configured female connector, protrudes from the casing and, when not in use, the male connector of the memory stick is often covered by a removable cap or other suitable cover for protection of that male connector. In the experience of this inventor, such caps or covers can become unintentionally lost or misplaced, which leaves the male connector exposed and subject to damage.

As also alluded to above, in order to access the data stored in the memory stick, the memory stick must be connected to a computer. This is typically accomplished by plugging the male connector of the memory stick into a host controller that is built into the computer, or into is a separate USB port or USB hub, for example. An important aspect of the memory stick is that it draws all of its necessary power from the supply provided by the host computer. Accordingly, memory sticks are “active” only when plugged into a corresponding computer connection. The memory stick used in accordance with the device of the present invention must have functional capabilities similar to those that are possessed by other similar computer memory devices. However, the exact nature of each of these capabilities is largely irrelevant for purposes of the present invention.

Well known in the art are certain “custom configured” memory sticks that are manufactured to represent various commercial logos and other types of promotional materials. Notwithstanding the existence of such custom configured memory sticks, most, if not all, of those memory sticks still require the use of a removable cap or other suitable cover for protection of the male connector of the memory stick. Again, in the experience of this inventor, such caps or covers can become unintentionally lost or misplaced, which leaves the male connector exposed and subject to damage.

In the view of this inventor, what is needed is a device for protecting the memory stick connector when the memory stick is not in use. When used as intended in this manner, the device would be both a functional and an ornamental structure. What is also needed is such a cover that, when the same cover is attached to the memory stick when it is in use, i.e. when the memory stick is “docked” to the input port of a computer, the cover would serve more as an ornamental structure.

Accordingly, it is an object of the present invention to provide a memory stick cover that is both ornamental and functional in its capabilities. It is another object of the present invention to provide such a cover that can be configured in an infinite variety of shapes such that the user will also consider the cover somewhat of a novelty item, configured in the shape of an item that is of particular interest to the user.

### SUMMARY OF THE INVENTION

The device of the present invention has obtained these objects. It provides for the use of a memory stick cover that is configured to be used by a consumer for receiving and protecting the connector of the memory stick when the memory stick is being transported and otherwise not in use. It also provides for a memory stick cover that is somewhat of a novelty item, the cover being removable from the connector end and placed over the opposite end of the memory stick when the memory stick is connected to a computer. The memory stick cover of the present invention may be configured of a moldable material such as rubber. Alternatively, it may consist of a hard-covered material with a rubber or other pliable material insert, the insert being configured to receive and protect the male connector of the memory stick.

The foregoing and other features of the memory stick cover of the present invention will be apparent from the detailed description that follows.

### BRIEF DESCRIPTION OF THE DRAWINGS

FIG. 1 is a top, front and right side perspective view of a generic form of cover in accordance with the present invention and showing the cover used with a flash memory stick device and also showing the device inserted into the cover.

FIG. 2 is the same view as shown in FIG. 1 but illustrating the flash memory stick device having been removed from the cover body.

FIG. 3 is a right side and partially cross-sectioned elevational view of the cover taken along lie 3-3 of FIG. 1.

FIG. 4 is a view similar to that shown in FIG. 3 but illustrating the flash memory stick device being inserted rearwardly into the cover whereby the male portion of the memory stick device is protected within the cover body.

FIG. 5 is a top, front and right side perspective view of one exemplary embodiment of the cover as used in a particular ornamental fashion, the cover taking the form of a toy car.

### DETAILED DESCRIPTION

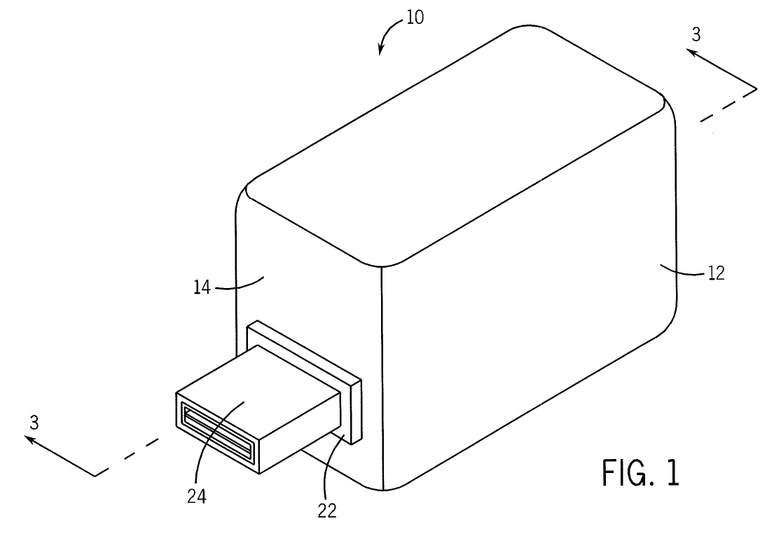

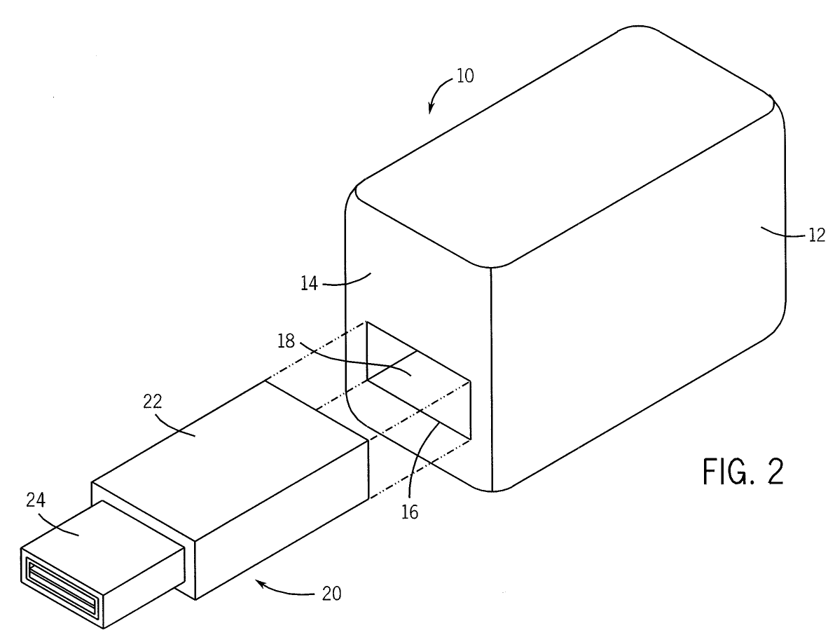

Referring now to the drawings in detail, wherein like numbered elements refer to like elements throughout, FIG. 1 illustrates a functional and ornamental cover, generally identified 10, that is constructed in accordance with the present invention. As shown, the cover 10 includes a cover body 12, the cover body 12 being presented in FIG. 1 in a purely generic form of embodiment for illustration purposes only. It is to be understood that the cover body 12 could take many shapes as will be apparent later in this detailed description. As shown in FIG. 1, the cover body 12 includes a forward face 14. As shown in FIG. 2, the forward face 14 of the cover body 12 includes an opening 16, the opening 16 being a point of access to a cavity 18 that is defined within the cover body 12.

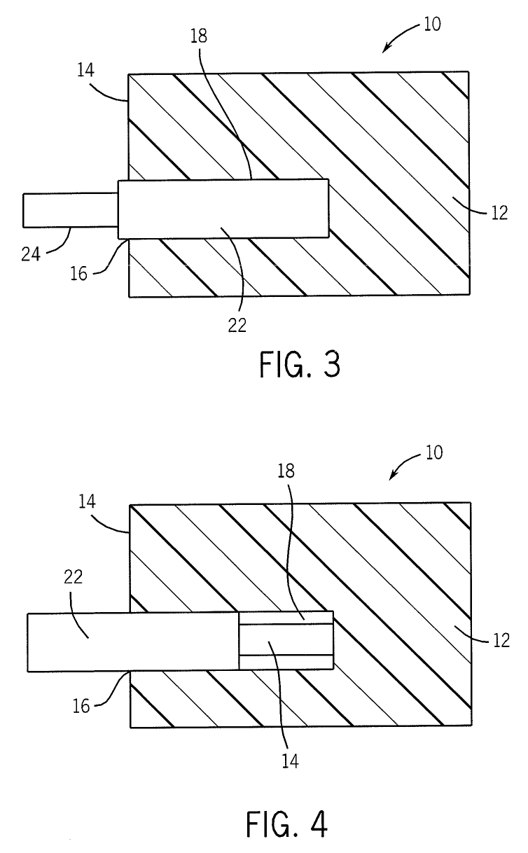

As shown in FIG. 1, the cover body 12 and the cover body cavity 18 are functionally adapted to receive the body 22 of a flash memory stick device, generally identified 20. The cavity 18 of the cover body 12 is dimensioned such that the body 22 of the flash memory stick device 20 can frictionally fit within the cavity 18. This insures that the flash memory stick device 20 will remain securely retained within the cavity 18 of the cover body 12 when the cover body 12 is used as intended. With the flash memory stick device 20 fully inserted into the cavity 18 of the cover body 12, only the male connector 24 of the flash memory stick device 20 and a relatively small portion of the body 22 of the flash memory stick device 20 will protrude from the cavity 18 of the cover body 12. See FIGS. 1, 2 and 3.

In the generic embodiment shown, it will also be seen that the cavity 18 is functionally adapted to receive the male connector 24 of the flash memory stick device 20 when the flash memory stick device 20 is removed from the cover body 12 and rotated 1800 as is shown in FIG. 4. FIG. 4 illustrates the mode in which the flash memory stick device 20 could be safely contained within the cover body 12 for purposes of transport.

It is to be understood that the cover 10 could be configured in any number of ornamental, decorative and/or novelty configurations. The preferred embodiment of the cover body 12 would be to manufacture it from a plastic-like or rubber-like material having a somewhat high coefficient of friction such that the body 22 of the flash is memory stick device 20 is maintained within the cavity 18 of the cover body 12. Absent this frictional fit, the flash memory stick device would tend to be easily dislodged from within the cavity 18. The use of a resilient plastic-like or rubber-like material also allows the deformation of the cover body 12 and the cavity 18 in the situation where the shape of the flash memory stick device 20 is different than the generally rectangularly-shaped cavity 18 as is illustrated herein. The cavity 18, as shown, is in the form of a right rectangular prism, also known as an “oblong prism” or a “cuboid.” That is, if the flash memory stick device 20 is a generally squared-off device, it will fit well within the similarly-shaped cavity 18. But where the flash memory stick device 20 has a more rounded contour to it or is slightly larger than the cavity 18, it will be necessary for the sidewalls of the cavity 18 to be flexible such that they can be pushed outwardly to allow for insertion of the flash memory stick device 10 into the cavity 18. Such materials that could accomplish this functionality would include any pliant rubber or plastic material. It would also be possible, and fully within the scope of this invention, to use a pliant rubber or plastic material that is surrounded by a shell or covering of harder material (not shown), the specific materials not being a limitation of the present invention. The material could be a hard plastic, thin metal or a combination of those materials. Either of these embodiments, a softer cover or a soft cover overlaid by a harder shell, would accomplish the intended result.

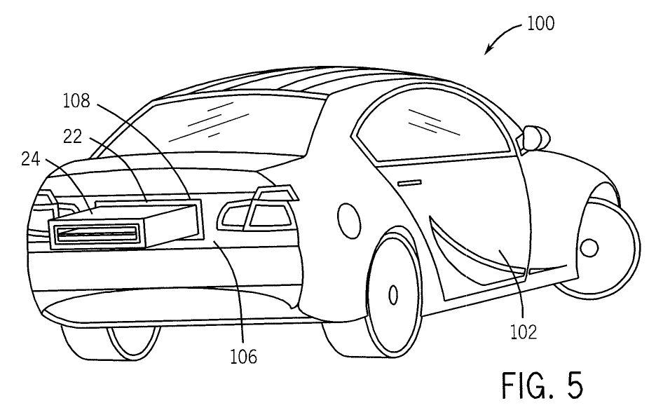

Referring now to FIG. 5, it will be seen that the cover, generally identified 100, is shown in a particular ornamental configuration, in this case a “novelty” item in the form of a toy car 102. The toy car 102 also includes a forward face 106, which is really the rear portion of the toy car 102, the front face 106 including a cavity 108. As alluded to earlier, the exact configuration of the cover 10, 100 is, as a practical matter, without limit. Any number of novelty configurations could be devised within the scope of the present invention. As long as the cover 10, 100 allows the insertion of a flash memory stick device 20 into it, such cover 10, 100 would be considered to be within the scope of the present invention.

It would also be possible to utilize small lights, or light-emitting diodes (“LEDs”) to provide the effect of headlights in the case of the toy car 102 or illuminated eyes in the case of an animal or human figurine (not shown). Such lights or LEDs could be used for other features of any particular cover design or configuration. The lights or LEDs could also be configured to illuminate only when the flash memory stick device 20 is in use. The energy source for such embodiment could be a separate direct current battery with a switch (not shown). Alternatively, the energy is source could be a small amount of electrical energy derived or diverted from the computer that is using the flash memory stick device 20. The present invention is not limited as to any particular use of lights or LEDs as an added enhancement to the device of the present invention.

The details of the invention having been disclosed in accordance with the foregoing, I claim:

1. A cover for a flash memory stick, said flash memory stick having a stick body, said cover comprising
a cover body,
a cavity defined within the cover body,
an opening, said opening being a point of access to the cavity defined within the cover body,
wherein the opening and cavity are functionally adapted to receive the stick body of the flash memory stick device therein.

2. The flash memory stick cover of claim 1 wherein the cavity of the cover body is dimensioned such that the stick body of the flash memory stick device frictionally fits within the cavity.

3. The flash memory stick cover of claim 1 wherein the cavity of the cover body is formed of a resilient plastic-like or rubber-like material having a high coefficient of friction such that the stick body of the flash memory stick device frictionally fits and is retained within the cavity.

4. The flash memory stick cover of claim 1 wherein the cover body and its cavity is formed of a resilient plastic-like or rubber-like material having a coefficient of friction sufficient to retain the stick body of the flash memory stick within the stick body cavity.

5. The flash memory stick cover of claim 4 wherein the cover body is further covered by one or both from a group consisting of a hard plastic material and a metal material.

6. The flash memory stick cover of claim 1 wherein the cover body cavity is formed in the shape of an oblong prism and wherein the cover body and the cover body cavity are made from a resilient plastic-like or rubber-like material, such material allowing the deformation of the cover body cavity when the shape of the flash memory stick device is different from the shape of the cover body cavity.

7. The flash memory stick cover of claim 1 wherein the cover body cavity is functionally adapted to receive the male connector of the flash memory stick device when the male connector is inserted into cover body cavity.

8. The flash memory stick cover of claim 1 wherein the cover body further comprises light emitting means.

9. The flash memory stick cover of claim 1 wherein the cover body comprises a novelty item.

10. A functional and ornamental cover for a flash memory stick, said flash memory stick having a stick body, said cover comprising
a cover body,
a cavity defined within the cover body,
an opening, said opening being a point of access to the cavity defined within the cover body,
wherein the opening and cavity are functionally adapted to receive the stick body of the flash memory stick device therein.

11. The functional and ornamental flash memory stick cover of claim 1 wherein the cavity of the cover body is dimensioned such that the stick body of the flash memory stick device frictionally fits within the cavity.

12. The functional and ornamental flash memory stick cover of claim 1 wherein the cavity of the cover body is formed of a resilient plastic-like or rubber-like material having a high coefficient of friction such that the stick body of the flash memory stick device frictionally fits and is retained within the cavity.

13. The functional and ornamental flash memory stick cover of claim 1 wherein the cover body and its cavity is formed of a resilient plastic-like or rubber-like material having a coefficient of friction sufficient to retain the stick body of the flash memory stick within the stick body cavity.

14. The functional and ornamental flash memory stick cover of claim 4 wherein the cover body is further covered by one or both from a group consisting of a hard plastic material and a metal material.

15. The functional and ornamental flash memory stick cover of claim 1 wherein the cover body cavity is formed in the shape of an oblong prism and wherein the cover body and the cover body cavity are made from a resilient plastic-like or rubber-like material, such material allowing the deformation of the cover body cavity when the shape of the flash memory stick device is different from the shape of the cover body cavity.

16. The functional and ornamental flash memory stick cover of claim 1 wherein the cover body cavity is functionally adapted to receive the male connector of the flash memory stick device when the male connector is inserted into cover body cavity.

17. The functional and ornamental flash memory stick cover of claim 1 wherein the cover body further comprises light emitting means.

18. The functional and ornamental flash memory stick cover of claim 1 wherein the cover body comprises a novelty item.
